(19) United States
(12) Patent Application Publication
(10) Pub. No.: US 2021/0074741 A1
(43) Pub. Date: Mar. 11, 2021

(54) DISPLAY SUBSTRATE, METHOD OF MANUFACTURING DISPLAY SUBSTRATE, AND DISPLAY DEVICE

(71) Applicant: HKC CORPORATION LIMITED, Shenzhen (CN)

(72) Inventors: Bangtong GE, Chongqing (CN); Tingting FU, Chongqing (CN)

(21) Appl. No.: 17/042,870

(22) PCT Filed: Dec. 26, 2018
(86) PCT No.: PCT/CN2018/123685

§ 371 Date: Sep. 28, 2020

(30) Foreign Application Priority Data
Nov. 14, 2018 (CN) 201811350776,0

(51) Int. Cl. H01L 27/12

(52) U.S. Cl. CPC H01L 27/1262; H01L 27/1237; H01L 27/1218

(57) ABSTRACT

This application discloses a display substrate, a method of manufacturing the display substrate, and a display device. The method of manufacturing the display substrate includes a step of: sequentially forming a first structural layer, a second structural layer, a third structural layer, a fourth structural layer, and a fifth structural layer stacked on a substrate, and after the second structural layer is formed and before the third structural layer is formed, further includes the following step: performing plasma cleaning on a surface of the second structural layer.

This application claims the priority to the Chinese Patent Application No. CN201811350776.0, filed with National Intellectual Property Administration, PRC on Nov. 14, 2018 and entitled “DISPLAY SUBSTRATE, METHOD OF MANUFACTURING DISPLAY SUBSTRATE, AND DISPLAY DEVICE”, which is incorporated herein by reference in its entirety.

### TECHNICAL FIELD

This application relates to the display technology field, and in particular, to a display substrate, a method of manufacturing the display substrate, and a display device.

### BACKGROUND

Statement herein merely provides background information related to this application and does not necessarily constitute the existing technology.

With development and advance of science and technology, due to hot spots such as thinness, power saving, and low radiation, liquid crystal display becomes the mainstream product and is widely applied. Most liquid crystal displays in the market are backlight liquid crystal displays, including a liquid crystal panel and backlight module. The working principle of the liquid crystal panel is: Liquid crystal molecules are placed between two parallel glass substrates, and a drive voltage is applied across the two glass substrates to control rotating directions of the liquid crystal molecules, so that light in the backlight module is refracted out to generate an image. A thin film transistor-liquid crystal display (TFT-LCD) has performance such as low power consumption, good picture quality, and a relatively high production yield and therefore has currently gradually been dominant in the field of display. Generally, a thin film transistor-liquid crystal display (TFT-LCD) includes a liquid panel and backlight module. The liquid panel includes a color filter substrate (CF Substrate), a thin film transistor substrate (TFT Substrate) and a plurality of masks, a plurality of transparent electrodes. The masks and the transparent electrodes are respectively mounted on opposite sides of the CF substrate and the TFT Substrate. Liquid crystal (LC) molecules is always sandwiched between the CF substrate and the TFT Substrate.

In the production process of the thin film transistor (TFT), stability of the TFT is particularly important. Always, a parameter of threshold voltage is an important evaluation standard for the stability of TFT. When the threshold voltage is less than 0, the device has to shut down the TFT device through a high gate-source voltage negative voltage, which affects the stability of the device.

### SUMMARY

This application provides a display substrate, a method of manufacturing the display substrate, and a display device that can improve stability of the device.

To achieve the foregoing objective, this application provides a method of manufacturing a display substrate, including a step of: sequentially forming a first structural layer, a second structural layer, a third structural layer, a fourth structural layer, and a fifth structural layer stacked on a substrate, and after the second structural layer is formed and before the third structural layer is formed, further including the following step: performing plasma cleaning a surface of the second structural layer or a surface of the third structural layer.

Optionally, the step of sequentially forming a first structural layer, a second structural layer, a third structural layer, a fourth structural layer, and a fifth structural layer stacked on a substrate includes:

forming a first metal layer on the substrate, and etching two sides of the first metal layer to form the first structural layer as a gate;

forming the second structural layer as a gate insulation layer on the gate, the gate insulation layer covering the gate;

performing plasma cleaning on the gate insulation layer;

forming the third structural layer as an active layer on the gate insulation layer;

forming the fourth structural layer on the active layer, the fourth structural layer including a source and a drain; and

forming the fifth structural layer on the source and the drain, the fifth structural layer including a passivation layer and a transparent electrode layer.

Optionally, in the step of performing plasma cleaning on the gate insulation layer, the plasma cleaning is performed by ionization of ammonia.

Optionally, in the step of performing plasma cleaning on the gate insulation layer, the plasma cleaning is performed by ionization of oxygen.

Optionally, in the step of performing plasma cleaning on the gate insulation layer, the plasma cleaning includes a first plasma cleaning and a second plasma cleaning, the first plasma cleaning is performed by ionization of hydrogen, and the second plasma cleaning is performed by ionization of nitrous oxide.

Optionally, in the step of performing plasma cleaning on the gate insulation layer, the plasma cleaning includes a first plasma cleaning and a second plasma cleaning, the first plasma cleaning is performed by ionization of hydrogen, and the second plasma cleaning is performed by ionization of oxygen on the gate insulation layer.

Optionally, the step of sequentially forming a first structural layer, a second structural layer, a third structural layer, a fourth structural layer, and a fifth structural layer stacked on a substrate includes:

forming the first structural layer on the substrate, the first structural layer including a source and a drain;

forming the second structural layer as an active layer on the source and the drain;

performing plasma cleaning on the active layer;

forming the third structural layer as a gate insulation layer on the active layer;

forming the fourth structural layer as a gate on the gate insulation layer; and

forming the fifth structural layer on the gate, the fifth structural layer including a passivation layer and a transparent electrode layer.

This application further discloses a display substrate, including: a substrate, a gate, a gate insulation layer, an active layer, a source, and a drain, the gate, the gate insulation layer, the active layer, the source and the drain are in order stacked on the substrate, wherein a contact surface located between the active layer and the gate insulation layer is plasma cleaned.

Optionally, the display substrate further includes: a plurality of thin film transistors and a plurality of pixel electrodes, where the plurality of pixel electrodes are controlled by the corresponding thin film transistor switches, the thin film transistor switch includes the gate, the gate insulation layer, the active layer, the source, and the drain, and the contact surface between the active layer and the gate insulation layer of the thin film transistor is plasma cleaned.

Optionally, the plasma includes nitrogen plasma and hydrogen plasma.

Optionally, the gate is arranged on the substrate; the gate insulation layer is arranged on the gate; an oxide layer is formed on the gate insulation layer, wherein, the oxide layer is formed when plasma cleaning a surface of the gate insulating layer; the active layer is arranged on the gate insulation layer, the source and the drain are respectively arranged on two sides of an upper surface of the active layer; and the display substrate further includes a passivation layer and a transparent electrode layer, the passivation layer and the transparent electrode layer are arranged on the source and the drain.

Optionally, the plasma is oxygen plasma.

Optionally, a thickness of the oxide layer ranges from 1 to 20 angstroms.

Optionally, the source and the drain are arranged on the substrate; the active layer is arranged on the source and the drain; an oxide layer is formed on the active layer, the oxide layer is formed when plasma cleaning a surface of the active layer; the gate insulation layer is arranged on the active layer; the gate is arranged on the gate insulation layer; and the display substrate further includes a passivation layer and a transparent electrode layer, the passivation layer and the transparent electrode layer are arranged on the gate.

Optionally, the plasma is oxygen plasma.

This application further discloses a display device, including a display panel, the display panel including the foregoing display substrate.

Optionally, the display substrate is an array substrate, the display panel further includes a common substrate, and the common substrate and the array substrate are opposite to each other.

Optionally, the display device is one of a twisted nematic display device, an in-plane switching display device, and a multi-domain vertical alignment display device.

In a process production procedure of the display substrate, the stability of the display substrate device is particularly important for product stability. A threshold voltage is a more important evaluation standard parameter for evaluating the stability of the device. A gate insulation layer and an active layer of the display substrate accumulate a large quantity of positive charges on interfaces to form an internal electric field, the internal electric field will attract channel electrons to form a conductive channel on the gate insulation layer, and the device needs a high gate-source voltage negative voltage to shut down the display substrate device, which affects the stability of the device. In the solution, plasma cleaning is used to treat the contact surface between the gate insulation layer and the active layer, the positive charges accumulated on the contact surface are eliminated, and a size of the internal electric field formed by the positive charges is reduced, thus improving the stability of the device.

### BRIEF DESCRIPTION OF DRAWINGS

The included accompanying drawings are used to provide further understanding of the embodiments of this application, constitute a part of the specification, and are used to illustrate implementations of this application and explain the principle of this application together with literal descriptions. Apparently, the accompanying drawings in the following descriptions are merely some embodiments of this application, and a person of ordinary skill in the art can also obtain other accompanying drawings according to these accompanying drawings without involving any creative effort. In the accompanying drawings:

FIG. 1 is a schematic diagram of a display substrate wherein ion distribution hasn't been treated according to an embodiment of this application.

FIG. 2 is a schematic diagram of a display substrate wherein ion distribution has been treated according to an embodiment of this application.

FIG. 3 is a flowchart of a method of manufacturing a display panel according to an embodiment of this application.

FIG. 4a to FIG. 4g are schematic diagrams of a display substrate according to an embodiment of this application.

FIG. 5 is a flowchart of a method of manufacturing a display panel according to another embodiment of this application.

FIG. 6 is a schematic diagram of a display device according to an embodiment of this application.

### DETAILED DESCRIPTION OF EMBODIMENTS

Specific structures and functional details disclosed herein are merely representative, and are intended to describe the objectives of the exemplary embodiments of this application. However, this application may be specifically implemented in many alternative forms, and should not be construed as being limited to the embodiments set forth herein.

In the description of this application, it should be understood that orientation or position relationships indicated by the terms such as “center”, “transverse”, “on”, “below”, “left”, “right”, “vertical”, “horizontal”, “top”, “bottom”, “inside”, and “outside” are based on orientation or position relationships shown in the accompanying drawings, and are used only for ease and brevity of illustration and description, rather than indicating or implying that the mentioned apparatus or component must have a particular orientation or must be constructed and operated in a particular orientation. Therefore, such terms should not be construed as limiting of this application. In addition, the terms such as “first” and “second” are used only for the purpose of description, and should not be understood as indicating or implying the relative importance or implicitly specifying the number of the indicated technical features. Therefore, a feature defined by “first” or “second” can explicitly or implicitly includes one or more of said features. In the description of this application, unless otherwise stated, “a plurality of” means two or more than two. In addition, the terms “include”, “comprise” and any variant thereof are intended to cover non-exclusive inclusion.

In the description of this application, it should be noted that unless otherwise explicitly specified or defined, the terms such as “mount”, “install”, “connect”, and “connection” should be understood in a broad sense. For example, the connection may be a fixed connection, a detachable connection, or an integral connection; or the connection may be a mechanical connection or an electrical connection; or the connection may be a direct connection, an indirect connection through an intermediary, or internal communication between two components. A person of ordinary skill in the art may understand the specific meanings of the foregoing terms in this application according to specific situations.

The terminology used herein is for the purpose of describing specific embodiments only and is not intended to be limiting of exemplary embodiments. As used herein, the singular forms “a”, “an” and “the” are intended to include the plural forms as well, unless the context clearly indicates otherwise. It should be further understood that the terms “include” and/or “comprise” when used in this specification, specify the presence of stated features, integers, steps, operations, units and/or components, but do not preclude the presence or addition of one or more other features, integers, steps, operations, units, components and/or combinations thereof.

This application is further described below with reference to the accompanying drawings and optional embodiments.

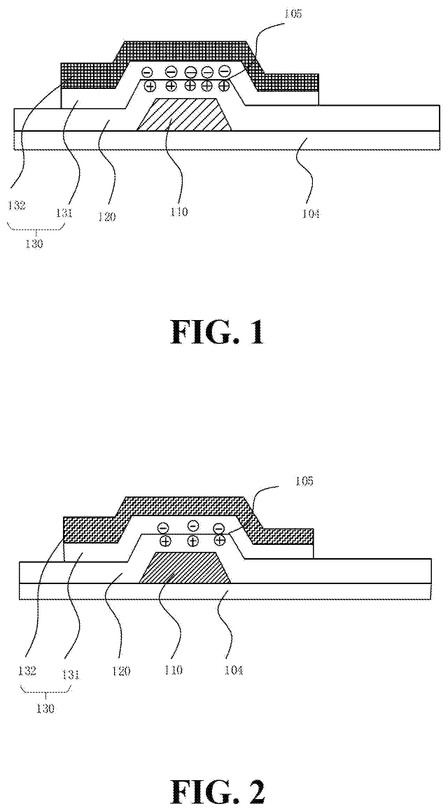

FIG. 1 is a schematic structural diagram of an undisclosed display substrate. The display substrate includes: a substrate 104, a gate 110, a gate insulation layer 120, and an active layer 130. The gate 110 is arranged on the substrate 104, the gate insulation layer 120 covers the gate 110, and the active layer 130 is arranged on the gate insulation layer 120. The active layer 130 includes: an amorphous silicon layer 131 and a doped layer 132. The doped layer 132 is arranged on the amorphous silicon layer 131. The amorphous silicon 131 is arranged on the gate insulation layer 120. A contact surface 105 between the gate insulation layer 120 and the active layer 130 accumulate a large quantity of positive charges to form an internal electric field. In a process production procedure of the display substrate, stability of the display substrate device is particularly important for product stability. A threshold voltage is a more important evaluation standard parameter for evaluating the stability of the device.

Embodiments of this application disclose a method of manufacturing a display substrate, FIG. 2 is a schematic diagram of a display substrate wherein ion distribution has been treated according to an embodiment of this application. The method includes a step of: sequentially forming a first structural layer, a second structural layer, a third structural layer, a fourth structural layer, and a fifth structural layer stacked on a substrate, and after the second structural layer is formed and before the third structural layer is formed, further includes the following step: performing plasma cleaning on a surface of the second structural layer or a surface of the third structural layer. In this solution, plasma cleaning is used to treat the contact surface 105 between the second structure layer (that is, 120 in FIG. 2) and the third structure layer (that is, 130 in FIG. 2). Compared with a solution with no treatment, the contact surface 105 between the second structure layer and the third structure layer of the display substrate shown in FIG. 1 accumulates a large quantity of positive charges to form an internal electric field, the internal electric field will attract channel electrons to form a conductive channel on the second structural layer, and the device needs a high gate-source voltage negative voltage to shut down the display substrate device, which affects the stability of the device. In this solution, after plasma cleaning, the positive charges accumulated on the contact surface 105 are eliminated, a quantity of positive charges obviously decreases, and a size of the internal electric field formed by the positive charges is reduced, thereby improving the stability of the device.

Correspondingly, the display substrate 101 includes: a substrate 104, a gate 110, a gate insulation layer 120, an active layer 130, a source, and a drain, the gate 110, the gate insulation layer 120, the active layer 130, the source, and the drain stacked on the substrate 104. The active layer 130 includes an amorphous silicon layer 131 and a doped layer 132. The contact surface 105 between the amorphous silicon layer 131 and the gate insulation layer 120 is plasma cleaned. The display substrate includes: a plurality of thin film transistor switches (TFT) and a plurality of pixel electrodes. The plurality of pixel electrodes is controlled by the corresponding thin film transistor switches. The thin film transistor switch includes the gate 110, the gate insulation layer 120, the active layer 130, the source, and the drain, and the contact surface between the active layer and the gate insulation layer of the thin film transistor is plasma cleaned.

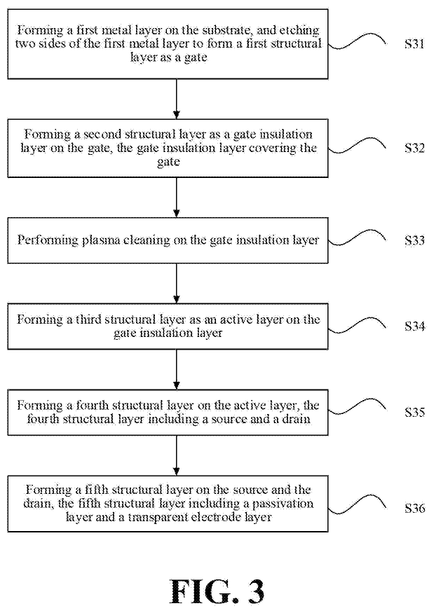

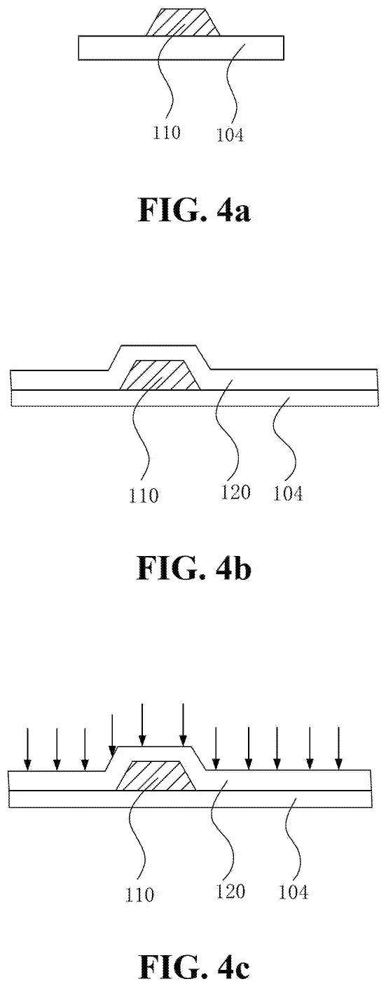

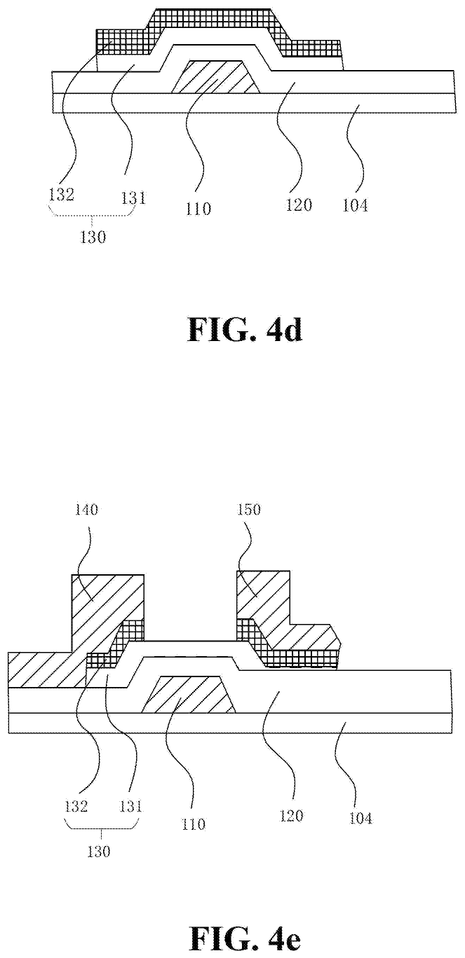

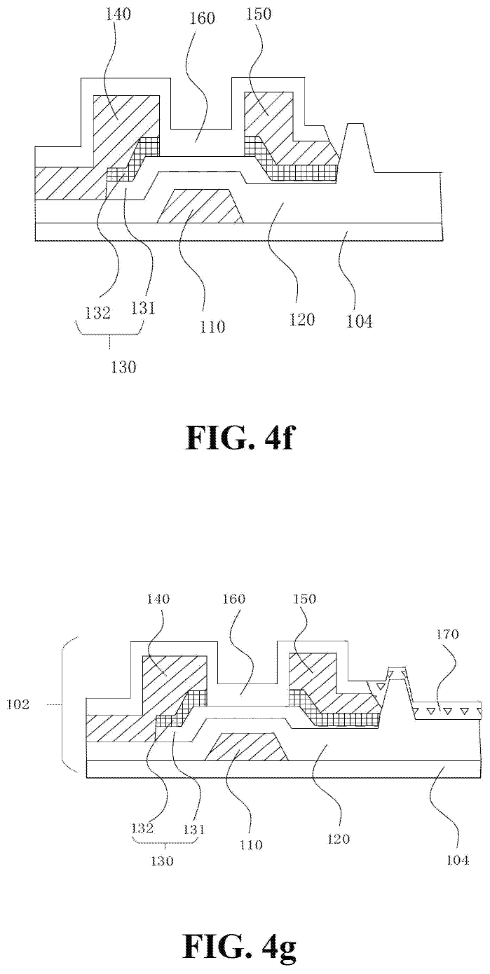

As shown in FIG. 3 and FIG. 4a to FIG. 4g, a method flow of a display substrate and a corresponding structural diagram are shown. In one or more embodiments, the step of sequentially forming a first structural layer, a second structural layer, a third structural layer, a fourth structural layer, and a fifth structural layer stacked on a substrate includes:

S31: forming a first metal layer on the substrate, and etching two sides of the first metal layer to form the first structural layer as a gate;

S32: forming the second structural layer as a gate insulation layer on the gate, the gate insulation layer covering the gate;

S33: performing plasma cleaning on the gate insulation layer;

S34: forming the third structural layer as an active layer on the gate insulation layer; where the active layer includes an amorphous silicon layer and a doped layer, the doped layer being arranged on the amorphous silicon layer;

S35: forming the fourth structural layer on the active layer, the fourth structural layer including a source and a drain; and

S36: forming the fifth structural layer on the source and the drain, the fifth structural layer including a passivation layer and a transparent electrode layer, and the transparent electrode layer being connected to the drain through a contact hole.

In this application, plasma cleaning is used to treat a surface of a gate insulation layer, the positive charges accumulated on the contact surface between the active layer and the gate insulation layer are eliminated, the size of the internal electric field formed by the positive charges is reduced, and the threshold voltage is greater than 0, thus improving the stability of the device; the plasma cleaning is performed on the gate insulation layer. Compared with ion implantation in a channel of the active layer, a dielectric property of the gate insulation layer is more stable, so that the TFT is more stable and has improved performance.

In one or more embodiments, in the step of performing ion implantation on the gate insulation layer, the plasma cleaning is performed by ionization of oxygen on the gate insulation layer to form oxygen plasma. Performing the plasma cleaning by ionization of oxygen on the gate insulation layer to form oxygen plasma, on one hand, can form a dense silicon oxide insulation layer, so that stability of the TFT is improved, and on the other hand, can also eliminate the positive charges accumulated on interfaces with the oxygen plasma being negative plasma, the size of the internal electric field formed by the positive charges is reduced, making the threshold voltage greater than 0, thus improving the stability of the device.

Correspondingly, in the display substrate, the gate 110 is arranged on the substrate 104. The gate insulation layer 120 is arranged on the gate 110. An oxide layer is formed on the gate insulation layer 120, the oxide layer is formed when plasma cleaning a surface of the gate insulating layer 120. The active layer 130 is arranged on the gate insulation layer 120. The source 140 and the drain 150 are respectively arranged on two sides of an upper surface of the active layer 130. The display substrate further includes a passivation layer 160 and a transparent electrode layer 170. The passivation layer 160 and the transparent electrode layer 170 are arranged on the drain 150 and the source 140. The active layer 130 includes an amorphous silicon layer 131 and a doped layer 132. The doped layer 132 is arranged on the amorphous silicon layer 131. In the display substrate, the thin film transistor is of a bottom gate type, and the gate insulation layer 120 is arranged on the gate 110. A thickness of the oxide layer ranges from 1 to 20 angstroms. By controlling a plasma treatment time, the thickness of the oxide layer can be controlled according to required performance requirements; an optional range of the thickness of the oxide layer is 1 to 20 angstroms.

Certainly, plasma cleaning may also be performed by gas such as ammonia or nitrous oxide on the gate insulation layer 120. In one or more embodiments, the step of performing ion implantation on the gate insulation layer, the plasma cleaning is performed by ionization of ammonia on the gate insulation layer to form nitrogen plasma and hydrogen plasma. In this solution, the plasma cleaning is performed by ionization of ammonia to form nitrogen plasma and hydrogen plasma to treat a surface of the gate insulation layer, the positive charges accumulated on the contact surface between the active layer and the gate insulation layer are eliminated, the size of the internal electric field formed by the positive charges is reduced, and the threshold voltage is greater than 0, thus improving the stability of the device.

Alternatively, in one or more embodiments, in the step of performing plasma cleaning on the gate insulation layer, the plasma cleaning includes a first plasma cleaning and a second plasma cleaning, the first plasma cleaning is performed by ionization of hydrogen to form hydrogen plasma, and the second plasma cleaning is performed by ionization of nitrous oxide or oxygen to form nitrogen plasma and oxygen plasma, or form only oxygen plasma. In this solution, the first plasma cleaning is performed by ionization of hydrogen to form hydrogen plasma, significantly reducing the size of the internal electric field formed by the positive charges. However, excessively much residual hydrogen plasma will affect the performance of the TFT, and consequently, many holes are formed on a surface of a film layer in a subsequent process. Then the second plasma cleaning is performed by using the nitrous oxide or oxygen, further cleaning the residual hydrogen plasma in the step of the first plasma cleaning while further reducing the size of the internal electric field formed by the positive charges, so that the performance of the display substrate is more stable.

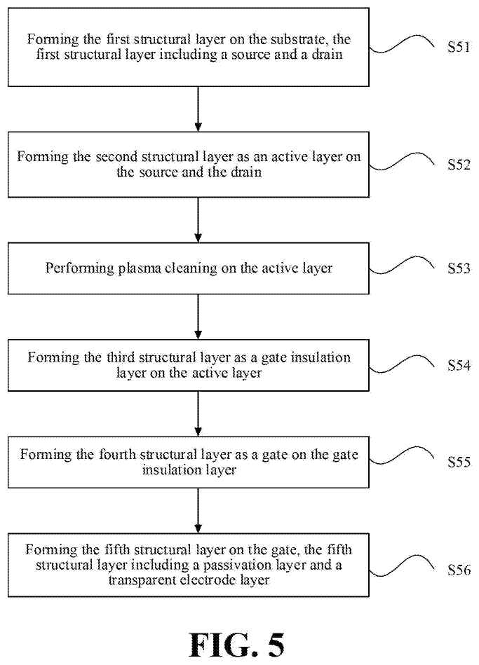

As shown in FIG. 5, a flowchart of another embodiment is disclosed. In one or more embodiments, the step of sequentially forming a first structural layer, a second structural layer, a third structural layer, a fourth structural layer, and a fifth structural layer stacked on a substrate includes:

S51: forming the first structural layer on the substrate, the first structural layer including a source and a drain;

S52: forming the second structural layer as an active layer on the source and the drain;

S53: performing plasma cleaning on the active layer;

S54: forming the third structural layer as a gate insulation layer on the active layer;

S55: forming the fourth structural layer as a gate on the gate insulation layer; and

S56: forming the fifth structural layer on the gate, the fifth structural layer including a passivation layer and a transparent electrode layer.

Corresponding, the source and the drain are arranged on the substrate; the active layer is arranged on the source and the drain; the active layer is an oxide layer formed after cleaning hydrogen plasma formed by ionization of hydrogen; the gate insulation layer is arranged on the active layer; the gate is arranged the gate insulation layer; and the display substrate further includes a passivation layer and a transparent electrode layer; the passivation layer and the transparent electrode layer being arranged on the gate.

For the TFT structure of a top gate type, in this solution, plasma cleaning is used to treat a surface of the active layer, so that the positive charges accumulated on the contact surface between the active layer and the gate insulation layer can be effectively eliminated, the size of the internal electric field formed by the positive charges is reduced, and the threshold voltage is greater than 0, thus improving the stability of the device.

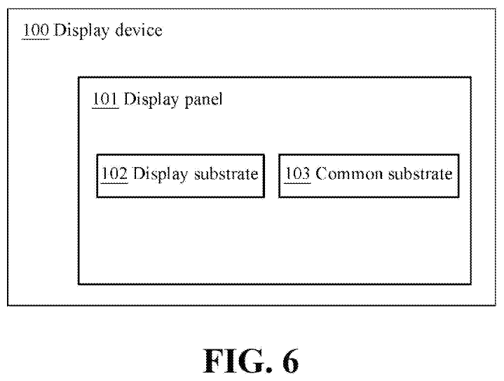

In another embodiment of this application, FIG. 6 is a block diagram of a display device, and a display device 100 is disclosed. The display device 100 includes a display panel 101, the display panel 101 includes a display substrate 102 and a common substrate 103, and the common substrate 103 and the display substrate 102 are opposite to each other. The display substrate is an array substrate, a color filter (that is, a color filter substrate) may be arranged on the common base, 103, or a color filter may not be arranged on the common substrate. The color filter is arranged on the array substrate by using a technology of color filter on array (COA).

It should be noted that, limitations to the steps involved in the solutions, without affecting implementation of specific solutions, are not considered to limit the sequence of steps. Preceding steps may be first performed or may be performed later, or steps may be performed at the same time. Provided that the solutions can be implemented, the limitations should all be considered as falling within the protection scope of this application.

The panel of this application may be a twisted nematic (TN) panel, an in-plane switching (IPS) panel, or a multi-domain vertical alignment (VA) panel, and may certainly be any other suitable types of panel.

The foregoing content describes this application in detail with reference to the specific implementations, and it should not be regarded that the specific implementations of this application are limited to these descriptions. A person of ordinary skill in the art can further make simple deductions or replacements without departing from the concept of this application, and such deductions or replacements should all be considered as falling within the protection scope of this application.

What is claimed is:

1. A method of manufacturing a display substrate, comprising a step of:
sequentially forming a first structural layer, a second structural layer, a third structural layer, a fourth structural layer, and a fifth structural layer stacked on a substrate, and after the second structural layer is formed and before the third structural layer is formed, further comprising the following step: performing plasma cleaning a surface of the second structural layer.

2. The method of manufacturing a display substrate according to claim 1, wherein the step of sequentially forming a first structural layer, a second structural layer, a third structural layer, a fourth structural layer, and a fifth structural layer stacked on a substrate comprises:
forming a first metal layer on the substrate, and etching two sides of the first metal layer to form the first structural layer as a gate;
forming the second structural layer as a gate insulation layer on the gate, the gate insulation layer covering the gate;
performing plasma cleaning on the gate insulation layer;
forming the third structural layer as an active layer on the gate insulation layer;
forming the fourth structural layer on the active layer, the fourth structural layer comprising a source and a drain; and
forming the fifth structural layer on the source and the drain, the fifth structural layer comprising a passivation layer and a transparent electrode layer.

3. The method of manufacturing a display substrate according to claim 2, wherein in the step of performing plasma cleaning on the gate insulation layer, the plasma cleaning is performed by ionization of ammonia.

4. The method of manufacturing a display substrate according to claim 2, wherein in the step of performing plasma cleaning on the gate insulation layer, the plasma cleaning is performed by ionization of oxygen.

5. The method of manufacturing a display substrate according to claim 2, wherein in the step of performing plasma cleaning on the gate insulation layer, the plasma cleaning comprises a first plasma cleaning and a second plasma cleaning, the first plasma cleaning is performed by ionization of hydrogen, and the second plasma cleaning is performed by ionization of nitrous oxide.

6. The method of manufacturing a display substrate according to claim 2, wherein in the step of performing plasma cleaning on the gate insulation layer, the plasma cleaning comprises a first plasma cleaning and a second plasma cleaning, the first plasma cleaning is performed by ionization of hydrogen, and the second plasma cleaning is performed by ionization of oxygen on the gate insulation layer.

7. The method of manufacturing a display substrate according to claim 1, wherein the step of sequentially forming a first structural layer, a second structural layer, a third structural layer, a fourth structural layer, and a fifth structural layer stacked on a substrate comprises:
forming the first structural layer on the substrate, the first structural layer comprising a source and a drain;
forming the second structural layer as an active layer on the source and the drain;
performing plasma cleaning on the active layer,
forming the third structural layer as a gate insulation layer on the active layer;
forming the fourth structural layer as a gate on the gate insulation layer; and
forming the fifth structural layer on the gate, the fifth structural layer comprising a passivation layer and a transparent electrode layer.

8. A display substrate, comprising:
a substrate, a gate, a gate insulation layer, an active layer, a source, and a drain, the gate, the gate insulation layer, the active layer, the source and the drain are in order stacked on the substrate,
wherein a contact surface located between the active layer and the gate insulation layer is plasma cleaned.

9. The display substrate according to claim 8, wherein the display substrate further comprises:
a plurality of thin film transistor switches, and
a plurality of pixel electrodes, controlled by the corresponding thin film transistor switches,
wherein the thin film transistor switch comprises the gate, the gate insulation layer, the active layer, the source, and the drain, and the contact surface between the active layer and the gate insulation layer of the thin film transistor switch is plasma cleaned.

10. The display substrate according to claim 8, wherein the plasma comprises nitrogen plasma and hydrogen plasma.

11. The display substrate according to claim 8, wherein
the gate is arranged on the substrate;
the gate insulation layer is arranged on the gate;
an oxide layer is formed on the gate insulation layer, wherein, the oxide layer is formed when plasma cleaning a surface of the gate insulating layer;
the active layer is arranged on the gate insulation layer;
the source and the drain are respectively arranged on two sides of an upper surface of the active layer; and
the display substrate further comprises a passivation layer and a transparent electrode layer, the passivation layer and the transparent electrode layer are arranged on the source and the drain.

12. The display substrate according to claim 11, wherein the plasma is oxygen plasma.

13. The display substrate according to claim 11, wherein a thickness of the oxide layer ranges from 1 to 20 angstroms.

14. The display substrate according to claim 8, wherein
the source and the drain are arranged on the substrate;
the active layer is arranged on the source and the drain;
an oxide layer is formed on the active layer, wherein, the oxide layer is formed when plasma cleaning a surface of the active layer,
the gate insulation layer is arranged on the active layer; and
the gate is arranged on the gate insulation layer;
the display substrate further comprises: a passivation layer and a transparent electrode layer, the passivation layer and the transparent electrode layer are arranged on the gate.

15. The display substrate according to claim 14, wherein the plasma is oxygen plasma.

16. A display device, comprising a display panel, the display panel comprising a display substrate, the display substrate comprising: a substrate, a gate, a gate insulation layer, an active layer, a source, and a drain, the gate, the gate insulation layer, the active layer, the source and the drain are in order stacked on the substrate,
wherein a contact surface between the active layer and the gate insulation layer is plasma cleaned.

17. The display device according to claim 16, wherein the display substrate is an array substrate, the display panel further comprises a common substrate, and the common substrate and the array substrate are opposite to each other.

18. The display device according to claim 16, wherein the display device is one of a twisted nematic display device, an in-plane switching display device, and a multi-domain vertical alignment display device.
